(19) United States
(12) Patent Application Publication
(10) Pub. No.: US 2024/0332267 A1
(43) Pub. Date: Oct. 3, 2024

(54) INTERPOSER FOR BACKSIDE POWER DELIVERY NETWORK

(71) Applicant: Adeia Semiconductor Bonding Technologies, Inc., San Jose, CA (US)

(72) Inventors: Belgacem HABA, Saratoga, CA (US); Cyprian Emeka UZOH, San Jose, CA (US); Rajesh KATKAR, Milpitas, CA (US)

(21) Appl. No.: 18/617,086

(22) Filed: Mar. 26, 2024

Related U.S. Application Data
(60) Provisional application No. 63/493,627, filed on Mar. 31, 2023.

(51) Int. Cl. H01L 25/10; H01L 21/48; H01L 23/00; H01L 23/48; H01L 23/498; H01L 23/528

(52) U.S. Cl. CPC H01L 25/105; H01L 21/4857; H01L 23/481; H01L 23/49838; H01L 23/5286; H01L 24/08; H01L 2224/08145; H01L 2224/08225

(57) ABSTRACT

In some embodiments, a structure comprises an active element having a frontside and a backside opposite the frontside, the active element having active circuitry nearer the frontside than the backside and a power redistribution element having a frontside hybrid bonded to the backside of the active element, the power redistribution element comprising a first plurality of contact pads on the frontside of the power redistribution element and a second plurality of contact pads on a backside of the power redistribution element opposite the frontside of the power redistribution element, a pitch of the first plurality of contact pads is smaller than a pitch of the second plurality of contact pads, the power redistribution element configured to supply at least one of power and ground to the active element.

### CROSS-REFERENCE TO RELATED APPLICATIONS

This application claims priority to U.S. Provisional Application No. 63/493,627, filed Mar. 31, 2023, titled “INTERPOSER FOR BACKSIDE POWER DELIVERY NETWORK,” the disclosure of which is incorporated herein by reference in its entirety for all purposes.

### BACKGROUND

### Field

This disclosure relates to semiconductor device structures and methods. In particular, some embodiments are directed to methods and structures for providing backside power delivery.

### Description of Related Art

The approaches described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

As features in semiconductor devices continue to shrink, power delivery issues are of increasing concern. Electrical isolation issues, limitations on feature sizes due to the high density of circuit elements and interconnects, losses due to traversing large numbers of metal layers, and so forth make it difficult to efficiently provide power to semiconductor devices.

### BRIEF DESCRIPTION OF THE DRAWINGS

These and other features, aspects, and advantages of the disclosure are described with reference to drawings of certain embodiments, which are intended to illustrate, but not to limit, the present disclosure. It is to be understood that the accompanying drawings, which are incorporated in and constitute a part of this specification, are for the purpose of illustrating concepts disclosed herein and may not be to scale.

FIG. 1A illustrates an example embodiment of a device structure that can provide power to a backside of an integrated device die.

FIG. 1B illustrates an example embodiment of a power delivery die having a redistribution layer.

FIG. 2 illustrates an example embodiment of a power delivery die having a redistribution layer and contact pads.

FIG. 3 illustrates an example embodiment of a stacked structure in which a power delivery die interfaces with an element via an interposer,

FIG. 4 illustrates a top-down view an example embodiment of a contact pad layout for an interposer.

FIGS. 5A-5C illustrate various example patterns for contact pads for an interposer according to some embodiments.

FIG. 6 illustrates an example embodiment of part of a power delivery die having separate voltage planes.

FIGS. 7A and 7B illustrate an example embodiment of a power delivery die having more than one power or ground line within the same plane.

FIGS. 8A and 8B illustrate example embodiments of a stacked structure that includes a passive element.

FIGS. 9A and 9B illustrate example embodiments of a power delivery die.

FIGS. 10A and 10B schematically illustrate a direct bonding process according to some embodiments.

### SUMMARY

The systems, methods, and devices described herein each have several aspects, no single one of which is solely responsible for its desirable attributes. Without limiting the scope of this disclosure, several non-limiting features will now be described briefly.

In one embodiment, the techniques described herein relate to a structure including: an active element including: a frontside and a backside opposite the frontside; a plurality of vias extending from the backside vertically through a portion of the active element; and an active region nearer to the frontside than the backside; a power redistribution element disposed on the backside of the active element, the power redistribution element including: a frontside and a backside opposite the frontside, a first plurality of contact pads disposed on the frontside; and a second plurality of contact pads disposed on the backside, wherein a pitch of the first plurality of contact pads is smaller than a pitch of the second plurality of contact pads, wherein the first plurality of contact pads is electrically coupled to the plurality of vias.

In some aspects, the techniques described herein relate to a structure, further including: a power delivery die including a frontside and a backside opposite the frontside, wherein the frontside is in electrical contact with the second plurality of contact pads of the power redistribution element.

In some aspects, the techniques described herein relate to a structure, wherein the power redistribution element is configured to carry power and ground and is not configured to carry logic signals.

In some aspects, the techniques described herein relate to a structure, wherein the power redistribution element includes an interposer.

In some aspects, the techniques described herein relate to a structure, wherein the power redistribution element further includes a hybrid bonding layer disposed on the frontside of the power redistribution element.

In some aspects, the techniques described herein relate to a structure, wherein the power redistribution element further includes a hybrid bonding layer disposed on the backside of the power redistribution element.

In some aspects, the techniques described herein relate to a structure, wherein the power redistribution element is at least partially deposited on the backside of the active element.

In some aspects, the techniques described herein relate to a structure, wherein the power redistribution element is at least partially deposited on the backside of the active element after thinning of the active element.

In some aspects, the techniques described herein relate to a structure, wherein the frontside of a power delivery die is hybrid bonded to the backside of the power redistribution element.

In some aspects, the techniques described herein relate to a structure, wherein the frontside of the power delivery die is hybrid bonded to the backside of the power redistribution element, and wherein the frontside of the power redistribution element is hybrid bonded to the backside of the active element.

In some aspects, the techniques described herein relate to a structure, further including a passive element disposed between the power delivery die and the power redistribution element.

In some aspects, the techniques described herein relate to a structure, wherein power is delivered through the power redistribution element to the backside of the active element.

In one embodiment, the techniques described herein relate to a structure including: an active element having a frontside and a backside opposite the frontside, the active element having active circuitry nearer the frontside than the backside; and a power redistribution element having a frontside hybrid bonded to the backside of the active element, the power redistribution element comprising a first plurality of contact pads on the frontside of the power redistribution element and a second plurality of contact pads on a backside of the power redistribution element opposite the frontside of the power redistribution element, wherein a pitch of the first plurality of contact pads is smaller than a pitch of the second plurality of contact pads, and wherein the power redistribution element is configured to supply at least one of power and ground to the active element.

In some aspects, the techniques described herein relate to a structure, wherein the active element comprises vias extending from the backside of the active element to the active circuitry.

In some aspects, the techniques described herein relate to a structure, further including: a power delivery die having a frontside and a backside opposite the frontside, wherein the frontside of the power delivery die is hybrid bonded to the backside of the power redistribution element.

In some aspects, the techniques described herein relate to a structure, wherein the at least one of power and ground is carried through the power redistribution element and delivered to the backside of the active element.

In one embodiment, the techniques described herein relate to an interposer including: a frontside surface; a backside surface opposite the frontside surface; a redistribution layer; a first plurality of contact pads disposed on the frontside surface of the interposer; and a second plurality of contact pads disposed on the backside surface of the interposer, wherein the first plurality of contact pads has a first pitch that is smaller than a second pitch of the second plurality of contact pads, wherein the first plurality of contact pads is configured to electrically connect to vias on a backside of an active element, wherein the second plurality of contact pads is configured to electrically connect to contact pads on a power delivery die, and wherein at least one of the frontside surface and the backside surfaces includes a hybrid bonding layer.

In some aspects, the techniques described herein relate to an interposer, wherein the first pitch is from about 50 nm to about 1000 nm, and wherein the second pitch is from about 1 μm to about 500 μm.

In some aspects, the techniques described herein relate to an interposer, wherein the interposer as a thickness of from about 1 μm to about 50 μm.

In some aspects, the techniques described herein relate to an interposer, wherein the second plurality of contact pads is arranged in a periodic pattern.

In some aspects, the techniques described herein relate to an interposer, wherein the frontside surface includes a hybrid bonding layer.

In some aspects, the techniques described herein relate to an interposer, wherein the backside surface includes a hybrid bonding layer.

In some aspects, the techniques described herein relate to an interposer, wherein the interposer includes a plurality of layers, wherein each layer is configured to carry a single voltage or ground, wherein each layer is separated from the other layers of the plurality of layers by a dielectric material.

In some aspects, the techniques described herein relate to an interposer, wherein the interposer is configured to carry power from the power delivery die at the backside surface of the interposer to the frontside surface of the interposer electrically connected to the vias on the backside of the active element.

In another embodiment, the techniques described herein relate to a method including: forming a first interposer including: a first frontside; a first backside opposite the first frontside; first frontside contacts disposed at the first frontside, the first frontside contacts arranged in a first frontside arrangement and configured to electrically connect to vias on a backside of a first active element; and first backside contacts disposed at the first backside, the first backside contacts arranged in a first backside pattern and configured to electrically connect to a first power delivery die; and forming a second interposer including: a second frontside; a second backside opposite the second frontside; second frontside contacts disposed at the second frontside, the second frontside contacts arranged in a second frontside arrangement and configured to electrically connect to vias on a backside of a second active element; and second backside contacts disposed at the second backside, the second backside contacts arranged in a second backside pattern and configured to electrically connect to a second power delivery die, wherein the first frontside arrangement is different from the second frontside arrangement, and wherein the first backside pattern is the same as the second backside pattern.

In some aspects, the techniques described herein relate to a method, wherein the first interposer further includes a first frontside hybrid bonding surface disposed on the first frontside.

In some aspects, the techniques described herein relate to a method, wherein the first interposer further includes a first backside hybrid bonding surface disposed on the first backside.

In some aspects, the techniques described herein relate to a method, where a pitch of the first backside pattern and the second backside pattern is greater than a pitch of the first frontside arrangement and a pitch of the second frontside arrangement.

In some aspects, the techniques described herein relate to a method, wherein the pitch of the first frontside arrangement is from about 100 nm to about 500 nm, wherein the pitch of the second frontside arrangement is from about 100 nm to about 500 nm, and wherein the pitch of the first backside pattern and the second backside pattern is from about 20 μm to about 500 μm.

In some aspects, the techniques described herein relate to a method, wherein the first interposer is configured to deliver a first power from the first power delivery die to the first backside of the first active element, and wherein the second interposer is configured to deliver a second power from the second power delivery die to the second backside of the second active element.

In another embodiment, the techniques described herein relate to a method including: forming a first interposer including: a first frontside; a first backside opposite the first frontside; first frontside contacts disposed at the first frontside, the first frontside contacts arranged in a first frontside arrangement and configured to electrically connect to vias on a backside of a first active element; and first backside contacts disposed at the first backside, the first backside contacts arranged in a first backside pattern and configured to electrically connect to a first power delivery die.

In some aspects, the techniques described herein relate to a method, wherein the first interposer further includes a first frontside hybrid bonding surface disposed on the first frontside.

In some aspects, the techniques described herein relate to a method, wherein the first interposer further comprises a first backside hybrid bonding surface disposed on the first backside.

In some aspects, the techniques described herein relate to a method, wherein the first interposer is configured to deliver a first power from the first power delivery to the first backside of the first active element.

In some aspects, the techniques described herein relate to a method including: forming a second interposer including: a second frontside; a second backside opposite the second frontside; second frontside contacts disposed at the second frontside, the second frontside contacts arranged in a second frontside arrangement and configured to electrically connect to vias on a backside of a second active element; and second backside contacts disposed at the second backside, the second backside contacts arranged in a second backside pattern and configured to electrically connect to a second power delivery die.

In some aspects, the techniques described herein relate to a method, wherein the first frontside arrangement is different from the second frontside arrangement.

In some aspects, the techniques described herein relate to a method, wherein the first backside pattern is the same as the second backside pattern.

In some aspects, the techniques described herein relate to a method, wherein a pitch of the first backside pattern and the second backside pattern is greater than a pitch of the first frontside arrangement and a pitch of the second frontside arrangement.

In some aspects, the techniques described herein relate to a method, wherein the pitch of the first frontside arrangement is from about 100 nm to about 500 nm, wherein the pitch of the second frontside arrangement is from about 100 nm to about 500 nm, and wherein the pitch of the first backside pattern and the second backside pattern is from about 20 μm to about 500 μm.

Various combinations of the above and below recited features, embodiments, and aspects are also disclosed and contemplated by the present disclosure.

Additional embodiments of the disclosure are described below in reference to the appended claims, which may serve as an additional summary of the disclosure.

### DETAILED DESCRIPTION

Although several embodiments, examples, and illustrations are disclosed below, it will be understood by those of ordinary skill in the art that the disclosure described herein extends beyond the specifically disclosed embodiments, examples, and illustrations and includes other uses of the disclosure and obvious modifications and equivalents thereof. Embodiments are described with reference to the accompanying figures, wherein like numerals refer to like elements throughout. The terminology used in the description presented herein is not intended to be interpreted in any limited or restrictive manner simply because it is being used in conjunction with a detailed description of some specific embodiments of the disclosure. In addition, embodiments can comprise several novel features. No single feature is solely responsible for its desirable attributes or is essential to practicing the disclosure herein described.

Backside power delivery can provide relief for issues related to increased density and shrinking feature sizes by separating power delivery from signal routing. However, backside power delivery can be challenging to implement. Some embodiments herein can enable easier and/or lower cost deployment of backside power delivery.

In conventional semiconductor devices, signal transmission and power delivery both take place through the frontside of the device. However, as device features continue to shrink, it is increasingly difficult to provide both power and signal through the frontside of a device without affecting the device performance. For example, as semiconductor devices become increasingly dense and complex, with each new advanced process node increasing the number of transistors or compute cells per unit area, the number of metal layers that include signal and power (or ground) lines to feed into these transistors also tends to increase, effectively increasing the path length of wires that carry power. The increased density of transistors in an active device region can result in a corresponding increased density of power and signal circuitry. To accommodate this increased density, the cross-sectional areas of vias and other circuitry can be reduced. However, this can result in higher impedance and increased power losses. Shrinking the cross-sectional area and increasing the length of power lines, for example, can result in significant power losses due to the high resistance of the thin copper typically used for frontside power delivery. For example, devices can be designed to accommodate power delivery losses (e.g., voltage drops) of about 10% from the power supply during transmission through the metal layers to the active device region. However, significantly larger drops can be seen at smaller or more advanced manufacturing nodes, especially when there is a large number of metal layers (e.g., about 10, about 15, about 20, or even more). In some processes, metal interconnects can comprise alternative materials such as cobalt, for example in lower back end of line (BEOL) levels, which can reduce power losses. However, the benefits of using other conductive materials are limited, and a different approach may be needed to address power and signal delivery obstacles as semiconductor device features continue to shrink. Moreover, power lines occupy significant real estate on the front side of a device. This can mean that a semiconductor device may be significantly larger in footprint in order to have sufficient area for the power and signal transmission lines to coexist on the frontside of the device.

Backside power delivery can relieve some of the problems associated with the scaling of semiconductor devices to smaller process nodes. For example, backside power delivery can alleviate congestion on the frontside by eliminating or reducing the need to route power via the frontside. Backside power delivery can enable wider and thicker power delivery and/or signal transmission lines. Backside power delivery can reduce the electrical path length between the power supply and the active device region. Such lines can have lower impedance, which can reduce power losses and/or improve signal integrity. Additionally, even without increasing the cross-sectional area of lines, backside power delivery can improve signal integrity because, for example, power delivery can be relatively far away from signal transmissions lines, which can reduce the potential for power transmission to interfere electromagnetically with signal transmission.

In addition to reduced losses and improved signal integrity, backside power delivery can be used as a tool to enable designers to create more compact devices. As mentioned briefly above, semiconductor devices can be larger than is otherwise necessary for the active device region when power and signal are both on the same side of the device. Such design decisions can play an increasingly important role in scaling as the benefits of moving to smaller, more advanced technology nodes offers diminishing returns.

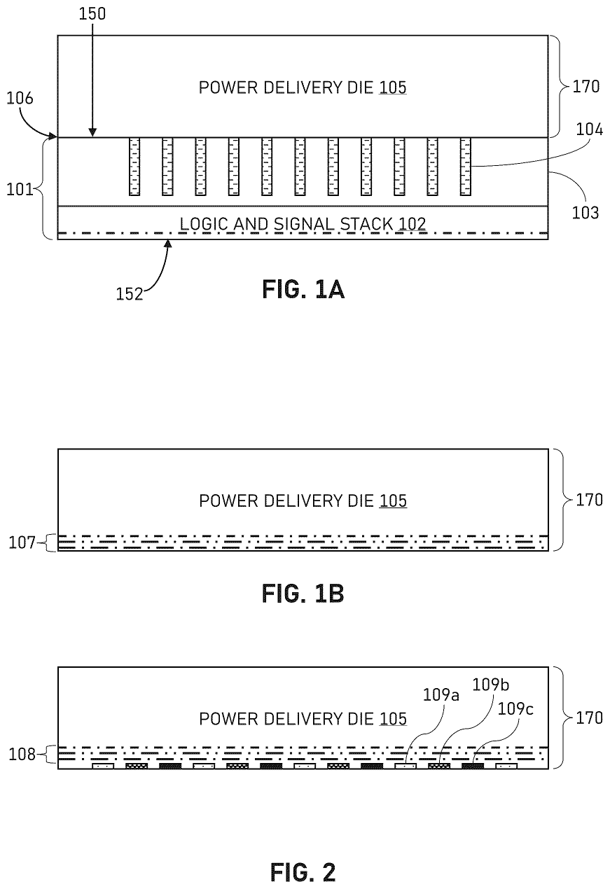

FIG. 1A schematically illustrates an example of providing power to a backside of an active element, such as an integrated device die. In FIG. 1A, an active element 101 can include a logic and signal stack 102 disposed near the frontside 152 of the active element 101. The logic and signal stack can include transistors, signal routing circuitry, and other components, including active devices, device cells and circuits, or electronic components to process, store or transmit signals. The active element 101 can include a back bulk portion 103 that includes vias 104 for delivering power to the active components of the logic and signal stack 102 via the backside 150 of the active element 101. The vias 104 can be in electrical contact with the logic and signal stack 102. In some embodiments, vias 104 can also be buried power rails, nano-TSVs, power TSVs, backside contact to source and drains, etc. A power delivery structure 170, having a power delivery die 105, can be bonded (e.g., hybrid bonded, as discussed in more detail herein) to a back surface 150 of the active element 101 via bond interface 106. Active circuitry (e.g., transistors) can be disposed closer to the front surface 152 than the back surface 150.

The vias 104 can be blind vias (e.g., vias that do not extend completely through the active element 101). In some embodiments, the vias 104 can comprise nanovias that connect directly to transistors of the logic and signal stack 102 located toward a frontside of the device, although in some embodiments the vias may not connect directly to the transistors. In some embodiments, the vias 104 can be electrically connected to one or more metal layers (or signal layers) on the frontside of the device to effectively deliver power from the frontside to transistors. In some embodiments, the vias 104 can deliver power into the side or back of the logic and signal stack 102 (e.g., to transistors of the logic and signal stack 102). In some embodiments, the power delivery structures or vias 104 can provide the power to transistor or device cells from the front side of the transistors or devices (e.g., contact to drain and source from front side via buried power rails, plugs, etc.), from the side of the transistor cells or devices (e.g., electrical contact to the source and drain region using buried power rails, power vias, nano-TSVs, etc.) or by directly contacting the source/drain regions from the backside (e.g., Back Side Contact or BSC). The vias can comprise one or more conductive materials such as, for example, poly-Si (which can have mechanical properties similar to a silicon substrate), cobalt, ruthenium, and/or tungsten. In some implementations, the vias can be formed relatively early during the manufacturing process of a semiconductor device, before front-end processes are complete. Thus, in some embodiments, it may be preferable to avoid the use of copper and/or nickel, which can diffuse into surrounding material and cause malfunctioning or failure. Additionally, the relatively low melting point of copper can present a problem when high temperature annealing and other high temperature processing steps are performed to make high quality, advanced node transistors. In some embodiments, the vias can be formed after front end processes are complete. In some embodiments, an active element can be thinned to expose vias formed before front end processes are complete. In some embodiments, a “drill and fill” approach can be used. For example, holes can be formed after thinning the active element, and these holes can be filled with conductive material (e.g., via deposition) after front end processes are complete.

As shown in FIG. 1B, the power delivery die 105 can include a redistribution layer 107. The redistribution layer 107 can be configured to distribute power and ground from the power delivery die 105 to the active element 101 through the vias 104. However, implementing such a power delivery die can be difficult. For example, the pitch between the vias 104 can be less than about 1 μm, for example from about 20 nm to about 1000 nm, e.g., in a range of about 20 nm to about 100 nm, or about 50 nm to about 1000 nm, or about 100 nm to about 1000 nm, or from about 100 nm to about 500 nm. While direct bonding (e.g., hybrid bonding) can be used, alignment challenges can be significant. Moreover, such an approach presents design, manufacturing, and storage complexities for manufacturers of power delivery dies. Different elements typically do not share a common layout for power vias. For example, via layouts can vary depending on the number of voltages needed, the layout of transistors in the logic and signal stack, the functional block layout, and so forth. Thus, if the redistribution layer is built into the power delivery die and interfaces directly with an element (e.g., directly with the power delivery vias of the element), a different power delivery die will need to be designed, manufactured, and warehoused for each different layout of vias of different elements, adding design expense and creating logistical hurdles.

Accordingly, it would be beneficial to have a universal interposer between the active element 101 and the power delivery die 105. The universal interposer can have a standardized layout on one side for interfacing with a power delivery die 105, while the other side can be customized for each different type of active element 101. Manufacturers of power delivery dies can design dies that interface with the standardized layout of the interposer and thereby avoid the need to customize a power delivery die for each type of element. It will be appreciated that some limited customization may still be performed. For example, a power delivery die can be made larger or smaller (e.g., have more or fewer contacts) depending upon the size of the element. Such customization can be relatively straightforward as the standardized layout can, in some embodiments, comprise a repeating pattern that may be easily expanded or contracted to fit a particular size of element or to accommodate a particular number of electrical connections.

In some embodiments, the interposer can include a deposited redistribution layer, a reconstituted layer, and so forth. In some embodiments, the interposer can include active circuitry, semiconductor devices, or transistors. In some embodiments, the interposer may not include active circuitry, semiconductor devices, or transistors. The interposer can have a smaller footprint, a bigger footprint, or the same footprint as a logic die or another element. In some embodiments, the interposer can extend beyond the edges of a logic die or another element. In some embodiments, the interposer can be a single layer. In some embodiments, the interposer can comprise multiple layers. For example, in some embodiments, an interposer can comprise one or more deposited redistribution layers and one or more bonded (e.g., hybrid bonded) layers. For example, it may be desirable to bond a first layer or first few layers on the backside of an element, where the relatively small pitches can make direct bonding difficult. Because the interposer carries only a limited number of signals (e.g., power, ground, and possibly some low speed signaling), redistribution can be fairly simple, and the interposer can be made thin. For example, the interposer may have a thickness of from about 0.5 μm to about 5 μm, for example from about 1 μm to about 2 μm. In some embodiments, the interposer can have a thickness of less than about 700 μm. In another embodiment, the interposer may be one or more routing layers that are deposited at the back of a thinned logic die on the exposed nanovias expanding the pitch of the nanovias on one side to an expanded standard pitch on the other side of the deposited routing layer stack.

In some embodiments, a power delivery die can be bonded (e.g., hybrid bonded) to the interposer. In some embodiments, the power delivery die can be surface mounted or soldered (e.g., using a flip chip process) to the interposer. In some embodiments, the power delivery die can be bonded to the interposer using thermocompression bonding. In some embodiments, external power to the power die can be provided using wire bonds or a pin grid array.

An example of a power delivery die 105 having a standardized contact pad layout is shown in FIG. 2. As shown in FIG. 2, the power delivery die 105 can include a redistribution layer 108 and contact pads 109a-c. Unlike the redistribution layer 107 of FIG. 1B, which is designed to electrically connected with the vias 104 of the active element 101, the redistribution layer 108 can be used to route power and ground signals to contact pads 109a-c having a known pattern for electrically connecting to an interposer. For example, in the example embodiment of FIG. 2, the contact pads 109a-c comprise a plurality of (e.g., three) different types of pads. For example, a first pad 109a can provide ground, a second pad 109b can provide a first supply voltage, and a third pad 109c can provide a second supply voltage different from the first supply voltage. It will be appreciated that such a layout is only one example, and different layouts may be used depending on, for example, the number of voltages to be supplied, the layout of the active element 101, and so forth.

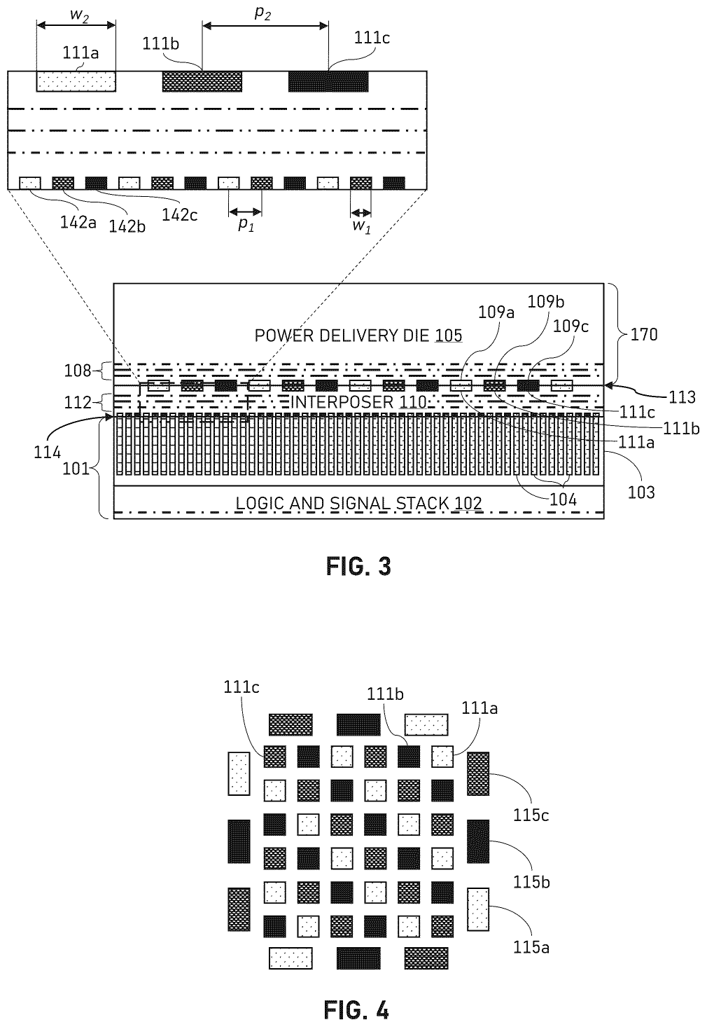

FIG. 3 illustrates an example embodiment of a stacked structure in which a power delivery structure 170 interfaces with active element 101 via an interposer 110. In some embodiments, power can be transferred to the power delivery structure 170 from outside the stacked structure (e.g., through wire bonds, etc.) and can traverse the circuitry of the power delivery structure 170. In some embodiments, the power delivery structure 170 can modify voltage amplitudes, frequencies, clock signals, timing of delivery of power, etc. In some embodiments, the power delivery structure 170 can include the power delivery die 105. In some embodiments, the power delivery structure 170 can additionally or alternatively include other structures such as integrated voltage regulators, and/or any other suitable active, passive, or dummy devices.

The power delivery die 105 can have circuitry (e.g., transistors) to control the distribution of power and ground to the active element 101. In some embodiments, the power delivery die 105 can comprise passive elements such as resistors, capacitors, inductors, and so forth. The contact pads 109a-c of the power delivery die 105 are in electrical contact with the contact pads 111a-c of the interposer 110 at bond interface 113. The contact pads 142a-c are in electrical contact with the logic and signal stack 102 at bond interface 114. The contact pads 142a-c can have a first pitch p₁ (e.g., the contact pads 142a-c of the interposer 110 can have a minimum first pitch corresponding to the smallest pitch of pads in the interposer 110) and the contact pads 111a-c can have a second pitch p₂. The pitch p₁ can be smaller than the pitch p₂. In some embodiments, the contact pads 142a-c can have a first width w₁ and the contact pads 111a-c can have a second width w₂. Since ground pads do not carry current, in some embodiments they may be smaller in size than other pads (e.g., smaller width, diameter, etc.), while voltage or power delivery pads can be larger (e.g., larger width, diameter, etc.). The vias 104 can have a pitch of from about 50 nm to about 1000 nm, for example from about 100 nm to about 500 nm. The pitch p₁ can be similar to or the same as the pitch of the vias 104 (e.g., from about 50 nm to about 1000 nm) or can be from about 10 nm to about 5000 nm. The pitch p₂ can be from about 0.2 μm to about 50 μm, about 1 μm to about 500 μm, or about 20 μm to about 500 μm, for example from about 20 μm to about 100 μm. The interposer 110 can be a thin structure that enables fanout from fine vias to coarser pads (e.g., contact pads 111a-c). While the contact pads 142a-c are depicted in a regularly repeating arrangement in FIG. 3, it will be appreciated that such an arrangement is not necessary. The contact pads 142a-c can be arranged according to a layout of the vias 104 of the active element 101, which may or may not be arranged in a regular pattern.

In some embodiments, the interposer 110 (e.g., power redistribution element) redistributes power. In some embodiments, the interposer 110 can redistribute signals (e.g., logic signals) in addition to power and/or ground signals. The signal received by the interposer 110 from the power delivery die 105 via the contact pads 111a-c can then be redistributed in a redistribution layer 112 of the interposer 110. The redistribution layer 112 can be configured to provide power and ground signals to the vias 104 of the active element 101. The interposer 110 can be in electrical communication with (e.g., electrically coupled to) the vias 104 of the back portion 103 of the active element 101 at bond interface 114. The power delivery die 105 can be bonded (e.g., hybrid bonded) to the interposer 110 via bond interface 113. In some embodiments, the redistribution layer 112 can be deposited on the vias 104 to form an interposer layer.

In some embodiments, the interposer 110 can be bonded (e.g., direct bonded or hybrid bonded) to the backside of the active element 101. The interposer 110 can be any power distribution element (e.g., power redistribution element), which can be a separate element (e.g., a separate interposer that can be bonded to the active element 101) or can be partially or fully deposited on a backside of the active element 101. For example, in other embodiments, the interposer 110 can be formed on the backside of the active element 101, for example using lithography, deposition, etching, polishing, and other processes known to those of skill in the art. As mentioned briefly above, while the interposer 110 is shown as a single unit in FIG. 3, in some embodiments the interposer 110 can be comprise multiple layers or multiple sub-units, some of which can be deposited (e.g., the layer or layers nearest the backside of the active element 101) and others of which can be direct bonded (e.g., hybrid bonded (e.g., the layer or layers nearest the power delivery die 105)).

FIG. 4 illustrates a top-down view a pad layout for an interposer. As shown in FIG. 4, the contact pads 111a-c can be distributed about the interposer in a regular pattern. For example, as discussed above, contact pad 111a can provide a first voltage (or ground), contact pad 111b can provide a second voltage (or ground), and contact pad 111c can provide a third voltage (or ground). In some implementations, there can be more or fewer types of contact pads. For example, some embodiments can include two types of contacts pads (e.g., one set of pads for providing ground and another set of pads for providing a supply voltage). In some embodiments, larger contact pads 115a-c may be distributed around the contact pads 111a-c, although in some embodiments, the larger contact pads 115a-c may not be present. It will be appreciated that FIG. 4 is merely for illustrative purposes. In an actual device, there may be many more pads than are illustrated in FIG. 4.

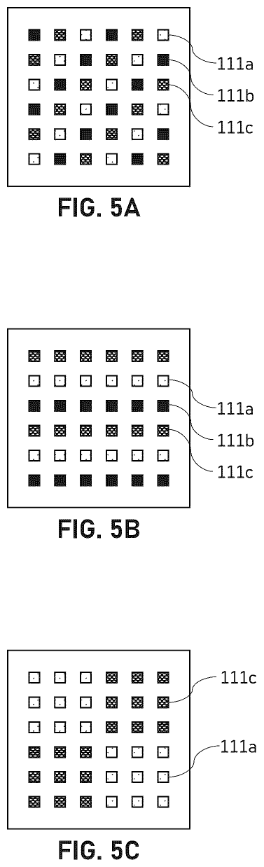

FIGS. 5A-5C illustrate various example patterns for contact pads for an interposer according to some embodiments. In the example of FIG. 5A, the contact pads 111a-c are arranged in a pattern that repeats horizontally and vertically, with each row beginning offset by one from the previous row. For example, in the second row from the top, the first contact pad on the left corresponds to the second contact pad in first row from the top. Such an arrangement can help ensure that the distance between a contact pad and a via that accesses the particular supply voltage (or ground) provided by the pad is relatively short, regardless of where the via is at on the element. For example, in FIG. 5A, which illustrates three voltages (or ground), each pad has nearest neighbors that include the other voltages (or ground). Such a design may be desirable for a generic interposer for use with elements having arbitrary via layouts. However, such a design may be sub-optimal for particular element layouts. For example, in the case of elements that use fin field effect transistors (FINFETs) or gate-all-around field effect transistors (GAA FETs) (e.g., nanoshect GAA FETs and/or nanowire GAA FETs), components of the element (e.g., FINFETs) often are arranged in rows. Accordingly, a structure such as the one depicted in FIG. 5B can be advantageous. For example, contact pads 111a-c can be arranged in rows that generally align with the FINFETs of the element. In some embodiments, each row can provide a particular power supply voltage (or ground). Such an arrangement can, for example, simplify a redistribution layer, reduce the path length that power (or one particular voltage) must travel before reaching the transistors of the element (thereby reducing power losses), and so forth.

FIG. 5C illustrates another example pattern for contact pads according to some embodiments. In FIG. 5C, contact pads are clustered. For example, a first region can include a first type of contact pad (e.g., supplying a first voltage or ground) and a second region can provide a second type of contact pad (e.g., supplying a second voltage or ground). Within a given region, there may be more than one type of contact pads. For example, a region can include contact pads for providing a supply voltage and contact pads for grounding. Such an arrangement may be desirable when, for example, the element is arranged into regions (e.g., a region for general computing tasks typically performed by a CPU, a region for graphical tasks, a region for communications, etc.) and said regions have different power needs, for example requiring different supply voltages. In some embodiments, an element may be a reconstituted element comprising multiple sub-elements which can be made according to different processes and/or which can have different power requirements. A layout such as the one depicted in FIG. 5C may be especially beneficial in such elements.

A power delivery die with a periodic or other standardized pattern for interfacing with an interposer can have a variety of structures. In some embodiments, a power delivery die can have separate power planes (also referred to herein as voltage planes). For example, in some embodiments, a power delivery die can have a separate power plane for each voltage to be supplied to an element. The power delivery die can also have one or more planes for providing grounding. In some embodiments, each voltage may be on its own voltage plane. In some embodiments, a combination of one or more voltages can be provided on a same plane, which can also include grounding. In some embodiments, there can be a ground plane disposed between two voltage planes, which can provide separation and shielding between the two voltage planes. The power delivery die can have a standardized interface (e.g., a standardized arrangement of contact pads) that can interface with a thin interposer to make electrical contact with an element such as a semiconductor die, which can have contacts at significantly smaller pitches and which may not have a standardized layout.

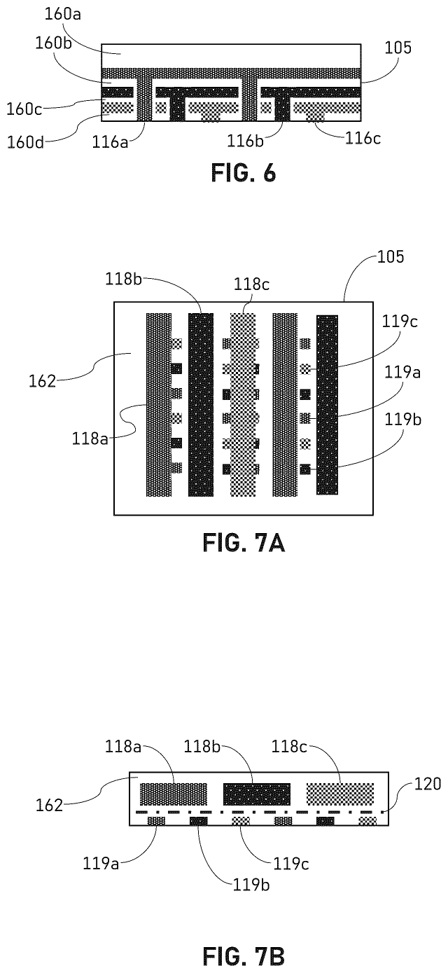

FIG. 6 illustrates an example embodiment of part of a power delivery die 105 in which separate voltage planes are used and can provide a desired pattern of contact pads. As illustrated in FIG. 6, the power delivery die 105 can have a first voltage/ground line 116a, a second voltage/ground line 116b, and a third voltage/ground line 116c, each voltage line disposed principally within its own horizontal plane. The first voltage/ground line 116a, second voltage/ground line 116b, and third voltage/ground line 116c can be embedded within dielectric layers 160a, 160b, 160c, and 160d, which can provide electrical isolation between the planes. Vertical lines extended toward a surface of the power delivery die. The vertically extending lines can extend to a surface of the power delivery die 105 to form a pattern of contact pads that can be bonded (e.g., direct bonded or hybrid bonded) to an interposer. For example, in some embodiments, the vertically extending lines can form patterns such as those shown in FIGS. 5A-C. As discussed above, it can be advantageous to have a ground layer in between voltage layers. Thus, for example, in some embodiments, first voltage/ground line 116a can carry one supply voltage and third voltage/ground line 116c can carry a second supply voltage, while second voltage/ground line 116b can provide ground.

While the design of FIG. 6 can have many advantages, forming multiple layers can be expensive and challenging, especially when many different voltages are to be provided. Thus, as mentioned above, in some embodiments one or more voltages and/or ground lines can be provided within the same plane. FIGS. 7A and 7B show an example embodiment in which multiple power/ground lines exist within the same plane. FIG. 7A shows a top view of such a power/ground line distribution, while FIG. 7B shows a cross section of such an embodiment.

FIG. 7A illustrates a top-down view of a power delivery die 105 according to some embodiments. The power delivery die 105 can include power delivery (or ground) lines 118a, 118b, and 118c. The power delivery lines 118a-c can all be in a common plane. Contact pads 119a, 119b, and 119c can be exposed at a major surface of the power delivery die, as shown in FIG. 7B. The contact pads 119a-c can be arranged in a periodic or other pattern, for example as shown in FIGS. 5A-5C. A redistribution layer 120 can be used to route the power from the power delivery lines 118a-c to the contact pads 119a-c. The power delivery lines 118a-c and contact pads 119a-c can be disposed in a dielectric material 162, which can provide electrical isolation.

In some embodiments, a power delivery die can be a passive device. For example, the power delivery die can redistribute power without any additional functionality. In some embodiments, the power delivery die can include additional circuitry including devices and transistors, such as buffer circuits to increase the uniformity of a voltage across a die. In some embodiments, separate passive elements can provide buffer circuits to enable more uniform power delivery. The passive element can include, for example, resistors, capacitors, inductors, and so forth.

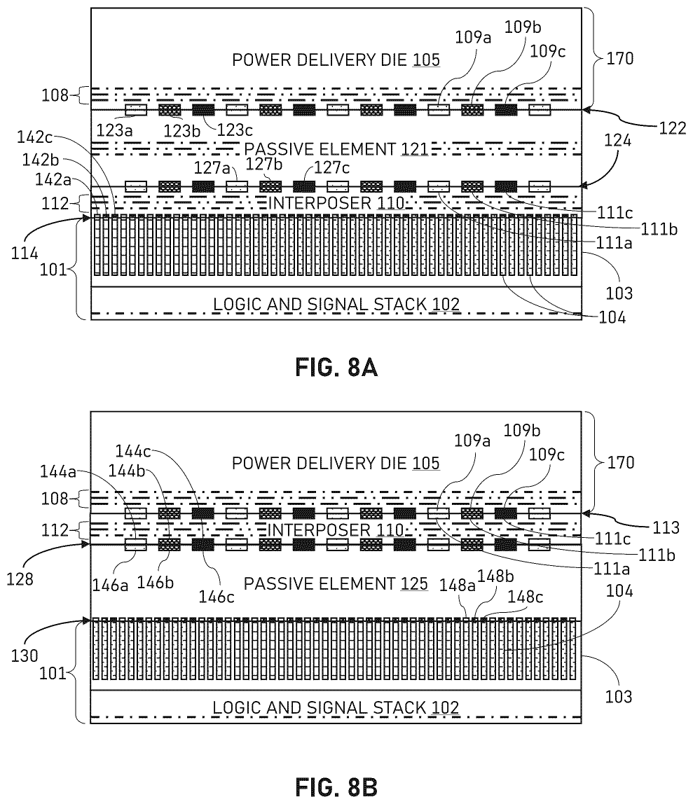

FIG. 8A illustrates an example embodiment that includes a separate passive element 121. In FIG. 8A, a power delivery die 105 can be bonded (e.g., direct bonded or hybrid bonded) to a passive element 121 at bond interface 122. The passive element 121 can include first contact pads 123a-c that are in electrical contact with the contact pads 109a-c of the power delivery die 105. The passive element 121 can be bonded (e.g., direct bonded or hybrid bonded) to the interposer 110 at bond interface 124. The passive element can include second contact pads 127a-c that are in electrical contact with the contact pads 111a-c of the interposer 110. The interposer can have contact pads 142a-c having a smaller pitch than the contact pads 111a-c, for example as described above with reference to FIG. 3. The passive element can include, for example, buffer circuitry which can be enable more uniform power delivery. The passive element can include one or more capacitors, resistors, inductors, integrated voltage regulators (IVR), and so forth. In some embodiments, the pitch between the first contact pads 123a-c can be different (e.g., larger) than a pitch between the second contact pads 127a-c. In some embodiments, the size (e.g., width or diameter) of the first contact pads 123a-c can be different (e.g., larger) than the size (e.g., width or diameter) of the second contact pads 127a-c.

FIG. 8B illustrates another example embodiment that includes a separate passive element 125. In FIG. 8B, the power delivery die 105 can be bonded (e.g., direct bonded or hybrid bonded) to the interposer 110 at bond interface 113. The interposer 110 can be bonded (e.g., direct bonded or hybrid bonded) to the passive element 125 at bond interface 128. The passive element 125 can be bonded (e.g., direct bonded or hybrid bonded) to the active element 101 at bond interface 130. The interposer depicted in FIG. 8B can have contact pads 111a-c and contact pads 144a-c. The contact pads 111a-c can be electrically connected to the contact pads 109a-c of the power delivery die 105. The interposer 110 can have a second set of contacts 144a-c that can be electrically connected to the passive element 125 via the contact pads 146a-c. The contact pads 144a-c can have a pitch that is smaller than, larger than, or about the same as the pitch of the contact pads 111a-c. The passive element 125 can include contacts 148a-c that are electrically connected to the vias 104 of the active element 101. The contacts 148a-c can have a pitch that matches the pitch of the vias 104. The pitch of the contacts 148a-c can be the same as the pitch p₁ of the contact pads 142a-c illustrated in FIG. 3. As illustrated by FIGS. 8A and 8B, the position of a passive element can vary within a stack and, depending upon the specific implementation, can be placed on either side of the interposer. For example, in FIG. 8A, the passive element 121 is disposed between the power delivery die 105 and the interposer 110, while FIG. 8B illustrates a passive element 125 disposed between an interposer 110 and active element 101 (e.g., a semiconductor die).

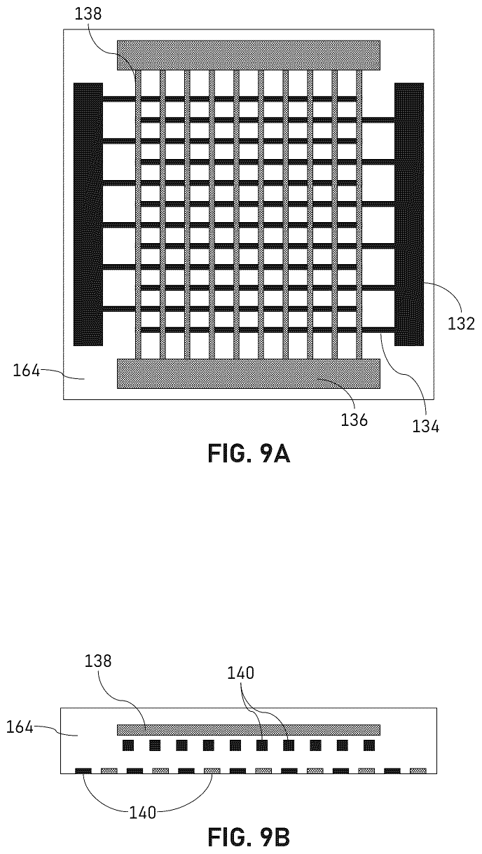

FIGS. 9A and 9B illustrate example embodiments of a power delivery die. In FIGS. 9A and 9B, different voltages can run orthogonal to one another in different planes. In FIGS. 9A and 9B, a first voltage (or ground) can be carried by power rail 132 and distributed via power lines 134. A second voltage (or ground) can be provided in another plane using power rail 136 and power lines 138. The power rail 132, power lines 134, power rail 136, and power lines 138 can be disposed in a dielectric 164, which can provide electrical isolation. The power lines 134 and power lines 138 can be electrically connected to contact pads 140. The power lines 134 and power lines 138 can be oriented perpendicularly to one another, which can reduce capacitive coupling between lines having different voltages, thereby enabling more uniform power distribution. In some embodiments, a power line may connect with only one power rail (as shown by power lines 134). However, other implementations are possible. For example, a power line may connect to one power rail at a first end and another power rail at the opposite end of the power line (as shown by power lines 138). Such a configuration may improve the uniformity of power distribution across an element. In some embodiments, a separate ground plane can be disposed between two power (or voltage) planes. In some embodiments, both power planes can be on the same side of a bond interface. In some embodiments, the power planes can be distributed on reconstituted logic wafers, reconstituted power wafers, and so forth. While two layers are depicted in FIGS. 9A and 9B, additional layers are contemplated. For example, in some embodiments, each plane can have wires with power or ground lines that run orthogonally to the nearest neighbor planes, and the number of planes is not necessarily limited. In some embodiments, the width or thickness of the power and ground lines can be the same or different.

While the above examples show a power die that interfaces with an element via an interposer, the disclosure is not strictly limited to power delivery. In some embodiments, the power die could include other components, such as power control circuitry, memory (e.g., static random-access memory, dynamic random-access memory, and so forth), additional logic, a capacitor component (or integrated passive device), integrated voltage regulator (IVR), and so forth. In some embodiments, the power delivery die can include analog circuitry, which tends to scale poorly and thus may be better suited to older, larger technology nodes.

### Direct Bonding

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

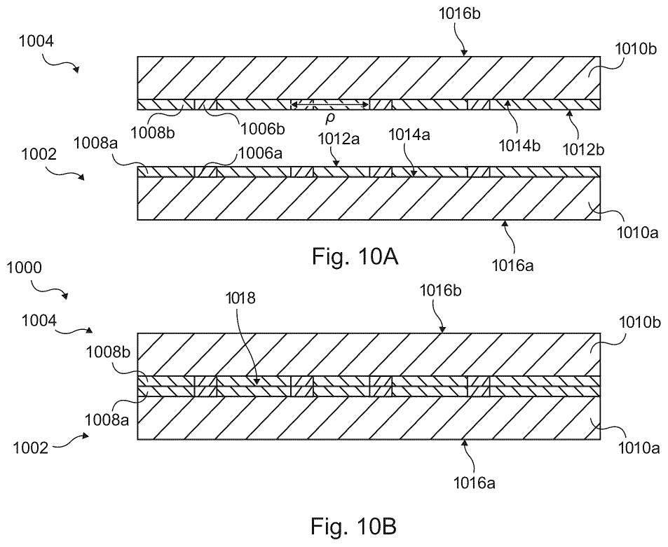

In various embodiments, the bonding layers 1008a and/or 1008b (see FIGS. 10A-10B) can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564, filed Jun. 30, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

FIGS. 10A and 10B schematically illustrate cross-sectional side views of first and second elements 1002, 1004 prior to and after, respectively, a process for forming a directly bonded structure, and more particularly a hybrid bonded structure, according to some embodiments. In FIG. 10B, a bonded structure 1000 comprises the first and second elements 1002 and 1004 that are directly bonded to one another at a bond interface 1018 without an intervening adhesive. Conductive features 1006a of a first element 1002 may be electrically connected to corresponding conductive features 1006b of a second element 1004. In the illustrated hybrid bonded structure 1000, the conductive features 1006a are directly bonded to the corresponding conductive features 1006b without intervening solder or conductive adhesive.

The conductive features 1006a and 1006b of the illustrated embodiment are embedded in, and can be considered part of, a first bonding layer 1008a of the first element 1002 and a second bonding layer 1008b of the second element 1004, respectively. Field regions of the bonding layers 1008a, 1008b extend between and partially or fully surround the conductive features 1006a, 1006b. The bonding layers 1008a, 1008b can comprise layers of non-conductive materials suitable for direct bonding, as described above, and the field regions are directly bonded to one another without an adhesive. The non-conductive bonding layers 1008a, 1008b can be disposed on respective front sides 1014a, 1014b of base substrate portions 1010a, 1010b.

The first and second elements 1002, 1004 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 1002, 1004, and back-end-of-line (BEOL) interconnect layers over such semiconductor portions. The bonding layers 1008a, 1008b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 1010a, 1010b, and can electrically communicate with at least some of the conductive features 1006a, 1006b. Active devices and/or circuitry can be disposed at or near the front sides 1014a, 1014b of the base substrate portions 1010a, 1010b, and/or at or near opposite backsides 1016a, 1016b of the base substrate portions 1010a, 1010b. In other embodiments, the base substrate portions 1010a, 1010b may not include active circuitry, but may instead comprise dummy substrates, passive interposers, passive optical elements (e.g., glass substrates, gratings, lenses), etc. The bonding layers 1008a, 1008b are shown as being provided on the front sides of the elements, but similar bonding layers can be additionally or alternatively provided on the back sides of the elements.

In some embodiments, the base substrate portions 1010a, 1010b can have significantly different coefficients of thermal expansion (CTEs), and bonding elements that include such different based substrate portions can form a heterogenous bonded structure. The CTE difference between the base substrate portions 1010a and 1010b, and particularly between bulk semiconductor (typically single crystal) portions of the base substrate portions 1010a, 1010b, can be greater than 5 ppm/° C. or greater than 10 ppm/° C. For example, the CTE difference between the base substrate portions 110a and 110b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 1010a, 1010b can comprise optoelectronic single crystal materials, including perovskite materials, that are useful for optical piezoelectric or pyroelectric applications, and the other of the base substrate portions 1010a, 1010b comprises a more conventional substrate material. For example, one of the base substrate portions 1010a, 1010b comprises lithium tantalate (LiTaO3) or lithium niobate (LiNbO3), and the other one of the base substrate portions 1010a, 1010b comprises silicon (Si), quartz, fused silica glass, sapphire, or a glass. In other embodiments, one of the base substrate portions 1010a, 1010b comprises a III-V single semiconductor material, such as gallium arsenide (GaAs) or gallium nitride (GaN), and the other one of the base substrate portions 1010a, 1010b can comprise a non-III-V semiconductor material, such as silicon (Si), or can comprise other materials with similar CTE, such as quartz, fused silica glass, sapphire, or a glass. In still other embodiments, one of the base substrate portions 1010a, 1010b comprises a semiconductor material and the other of the base substrate portions 1010a, 1010b comprises a packaging material, such as a glass, organic or ceramic substrate.

In some arrangements, the first element 1002 can comprise a singulated element, such as a singulated integrated device die. In other arrangements, the first element 1002 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 1004 can comprise a singulated element, such as a singulated integrated device die. In other arrangements, the second element 1004 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 1002, 1004 are shown, any suitable number of elements can be stacked in the bonded structure 1000. For example, a third element (not shown) can be stacked on the second element 1004, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 1002. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 1008a, 1008b, the bonding layers 1008a, 1008b can be prepared for direct bonding. Non-conductive bonding surfaces 1012a, 1012b at the upper or exterior surfaces of the bonding layers 1008a, 1008b can be prepared for direct bonding by polishing, for example, by chemical mechanical polishing (CMP). The roughness of the polished bonding surfaces 1012a, 1012b can be less than 30 Å rms. For example, the roughness of the bonding surfaces 1012a and 1012b can be in a range of about 0.1 Å rms to 15 Å rms, 0.5 Å rms to 10 Å rms, or 1 Å rms to 5 Å rms. Polishing can also be tuned to leave the conductive features 1006a, 1006b recessed relative to the field regions of the bonding layers 1008a, 1008b.

Preparation for direct bonding can also include cleaning and exposing one or both of the bonding surfaces 1012a, 1012b to a plasma and/or etchants to activate at least one of the surfaces 1012a, 1012b. In some embodiments, one or both of the surfaces 1012a, 1012b can be terminated with a species after activation or during activation (e.g., during the plasma and/or etch processes). Without being limited by theory, in some embodiments, the activation process can be performed to break chemical bonds at the bonding surface(s) 1012a, 1012b, and the termination process can provide additional chemical species at the bonding surface(s) 1012a, 1012b that alters the chemical bond and/or improves the bonding energy during direct bonding. In some embodiments, the activation and termination are provided in the same step, e.g., a plasma to activate and terminate the surface(s) 1012a, 1012b. In other embodiments, one or both of the bonding surfaces 1012a, 1012b can be terminated in a separate treatment to provide the additional species for direct bonding. In various embodiments, the terminating species can comprise nitrogen. For example, in some embodiments, the bonding surface(s) 1012a, 1012b can be exposed to a nitrogen-containing plasma. Other terminating species can be suitable for improving bonding energy, depending upon the materials of the bonding surfaces 1012a, 1012b. Further, in some embodiments, the bonding surface(s) 1012a, 1012b can be exposed to fluorine. For example, there may be one or multiple fluorine concentration peaks at or near a bond interface 1018 between the first and second elements 1002, 1004. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 1000, the bond interface 1018 between two non-conductive materials (e.g., the bonding layers 1008a, 1008b) can comprise a very smooth interface with higher nitrogen (or other terminating species) content and/or fluorine concentration peaks at the bond interface 1018. In some embodiments, the nitrogen and/or fluorine concentration peaks may be detected using various types of inspection techniques, such as SIMS techniques. The polished bonding surfaces 1012a and 1012b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 1008a and 1008b can be directly bonded to one another without an adhesive. In some embodiments, the elements 1002, 1004 are brought together at room temperature, without the need for application of a voltage, and without the need for application of external pressure or force beyond that used to initiate contact between the two elements 1002, 1004. Contact alone can cause direct bonding between the non-conductive surfaces of the bonding layers 1008a, 1008b (e.g., covalent dielectric bonding). Subsequent annealing of the bonded structure 1000 can cause the conductive features 1006a, 1006b to directly bond.

In some embodiments, prior to direct bonding, the conductive features 1006a, 1006b are recessed relative to the surrounding field regions, such that a total gap between opposing contacts after dielectric bonding and prior to anneal is less than 15 nm, or less than 10 nm. Because the recess depths for the conductive features 1006a and 1006b can vary across each element, due to process variation, the noted gap can represent a maximum or an average gap between corresponding conductive features 1006a, 1006b of two joined elements (prior to anneal). Upon annealing, the conductive features 1006a and 1006b can expand and contact one another to form a metal-to-metal direct bond.

During annealing, the conductive features 1006a, 1006b (e.g., metallic material) can expand while the direct bonds between surrounding non-conductive materials of the bonding layers 1008a, 1008b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials' melting temperature, such that bonds can form with lower anneal temperatures compared to soldering or thermocompression bonding.

In various embodiments, the conductive features 1006a, 1006b can comprise discrete pads, contacts, electrodes, or traces at least partially embedded in the non-conductive field regions of the bonding layers 1008a, 1008b. In some embodiments, the conductive features 1006a, 1006b can comprise exposed contact surfaces of TSVs (e.g., through silicon vias).

As noted above, in some embodiments, in the elements 1002, 1004 of FIG. 1A prior to direct bonding, portions of the respective conductive features 1006a and 1006b can be recessed below the non-conductive bonding surfaces 1012a and 1012b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 1006a, 1006b or to average depths of the recesses relative to local non-conductive field regions. Even for an individual conductive feature 1006a, 1006b, the vertical recess can vary across the feature, and so can be measured at or near the lateral middle or center of the cavity in which a given conductive feature 1006a, 1006b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 1006a, 1006b across the direct bond interface 1018 (e.g., small or fine pitches for regular arrays).

In some embodiments, a pitch p of the conductive features 1006a, 1006b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 1006a and 1006b to one of the lateral dimensions (e.g., a diameter) of the bonding pad is less than is less than 20, or less than 10, or less than 5, or less than 3 and sometimes desirably less than 2. In various embodiments, the conductive features 1006a and 1006b and/or traces can comprise copper or copper alloys, although other metals may be suitable, such as nickel, aluminum, or alloys thereof. The conductive features disclosed herein, such as the conductive features 1006a and 1006b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 1002, 1004, as shown, the orientations of one or more conductive features 1006a, 1006b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 1006b in the bonding layer 1008b (and/or at least one internal conductive feature, such as a BEOL feature) of the upper element 1004 may be tapered or narrowed upwardly, away from the bonding surface 1012b. By way of contrast, at least one conductive feature 1006a in the bonding layer 1008a (and/or at least one internal conductive feature, such as a BEOL feature) of the lower element 1002 may be tapered or narrowed downwardly, away from the bonding surface 1012a. Similarly, any bonding layers (not shown) on the backsides 1016a, 1016b of the elements 1002, 1004 may taper or narrow away from the backsides, with an opposite taper orientation relative to front side conductive features 1006a, 1006b of the same element.

As described above, in an anneal phase of hybrid bonding, the conductive features 1006a, 1006b can expand and contact one another to form a metal-to-metal direct bond. In some embodiments, the materials of the conductive features 1006a, 1006b of opposite elements 1002, 1004 can interdiffuse during the annealing process. In some embodiments, metal grains grow into each other across the bond interface 1018. In some embodiments, the metal is or includes copper, which can have grains oriented along the 111 crystal plane for improved copper diffusion across the bond interface 1018. In some embodiments, the conductive features 1006a and 1006b may include nanotwinned copper grain structure, which can aid in merging the conductive features during anneal. There is substantially no gap between the non-conductive bonding layers 1008a and 1008b at or near the bonded conductive features 1006a and 1006b. In some embodiments, a barrier layer may be provided under and/or laterally surrounding the conductive features 1006a and 1006b (e.g., which may include copper). In other embodiments, however, there may be no barrier layer under the conductive features 1006a and 1006b.

### Additional Embodiments

In the foregoing specification, the systems and processes have been described with reference to specific embodiments thereof. It will, however, be evident that various modifications and changes may be made thereto without departing from the broader spirit and scope of the embodiments disclosed herein. The specification and drawings are, accordingly, to be regarded in an illustrative rather than restrictive sense.

Indeed, although the systems and processes have been disclosed in the context of certain embodiments and examples, it will be understood by those skilled in the art that the various embodiments of the systems and processes extend beyond the specifically disclosed embodiments to other alternative embodiments and/or uses of the systems and processes and obvious modifications and equivalents thereof. In addition, while several variations of the embodiments of the systems and processes have been shown and described in detail, other modifications, which are within the scope of this disclosure, will be readily apparent to those of skill in the art based upon this disclosure. It is also contemplated that various combinations or sub-combinations of the specific features and embodiments of the embodiments may be made and still fall within the scope of the disclosure. It should be understood that various features and embodiments of the disclosed embodiments can be combined with, or substituted for, one another in order to form varying modes of the embodiments of the disclosed systems and processes. Any methods disclosed herein need not be performed in the order recited. Thus, it is intended that the scope of the systems and processes herein disclosed should not be limited by the particular embodiments described above.

It will be appreciated that the systems and methods of the disclosure each have several innovative embodiments, no single one of which is solely responsible or required for the desirable attributes disclosed herein. The various features and processes described above may be used independently of one another or may be combined in various ways. All possible combinations and sub-combinations are intended to fall within the scope of this disclosure.

Certain features that are described in this specification in the context of separate embodiments also may be implemented in combination in a single embodiment. Conversely, various features that are described in the context of a single embodiment also may be implemented in multiple embodiments separately or in any suitable sub-combination. Moreover, although features may be described above as acting in certain combinations and even initially claimed as such, one or more features from a claimed combination may in some cases be excised from the combination, and the claimed combination may be directed to a sub-combination or variation of a sub-combination. No single feature or group of features is necessary or indispensable to each and every embodiment.

It will also be appreciated that conditional language used herein, such as, among others, “can,” “could,” “might,” “may,” “for example,” and the like, unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without author input or prompting, whether these features, elements and/or steps are included or are to be performed in any particular embodiment. The terms “comprising,” “including,” “having,” and the like are synonymous and are used inclusively, in an open-ended fashion, and do not exclude additional elements, features, acts, operations, and so forth. In addition, the term “or” is used in its inclusive sense (and not in its exclusive sense) so that when used, for example, to connect a list of elements, the term “or” means one, some, or all of the elements in the list. In addition, the articles “a,” “an,” and “the” as used in this application and the appended claims are to be construed to mean “one or more” or “at least one” unless specified otherwise. Similarly, while operations may be depicted in the drawings in a particular order, it is to be recognized that such operations need not be performed in the particular order shown or in sequential order, or that all illustrated operations be performed, to achieve desirable results. Further, the drawings may schematically depict one or more example processes in the form of a flowchart. However, other operations that are not depicted may be incorporated in the example methods and processes that are schematically illustrated. For example, one or more additional operations may be performed before, after, simultaneously, or between any of the illustrated operations. Additionally, the operations may be rearranged or reordered in other embodiments. Additionally, other embodiments are within the scope of the following claims. In some cases, the actions recited in the claims may be performed in a different order and still achieve desirable results.

Further, while the methods and devices described herein may be susceptible to various modifications and alternative forms, specific examples thereof have been shown in the drawings and are herein described in detail. It should be understood, however, that the embodiments are not to be limited to the particular forms or methods disclosed, but, to the contrary, the embodiments are to cover all modifications, equivalents, and alternatives falling within the spirit and scope of the various implementations described and the appended claims. Further, the disclosure herein of any particular feature, aspect, method, property, characteristic, quality, attribute, element, or the like in connection with an implementation or embodiment can be used in all other implementations or embodiments set forth herein. Any methods disclosed herein need not be performed in the order recited. The methods disclosed herein may include certain actions taken by a practitioner; however, the methods can also include any third-party instruction of those actions, either expressly or by implication. The ranges disclosed herein also encompass any and all overlap, sub-ranges, and combinations thereof. Language such as “up to,” “at least,” “greater than,” “less than,” “between,” and the like includes the number recited. Numbers preceded by a term such as “about” or “approximately” include the recited numbers and should be interpreted based on the circumstances (for example, as accurate as reasonably possible under the circumstances, for example ±5%, ±10%, ±15%, etc.). For example, “about 3.5 mm” includes “3.5 mm.” Phrases preceded by a term such as “substantially” include the recited phrase and should be interpreted based on the circumstances (for example, as much as reasonably possible under the circumstances). For example, “substantially constant” includes “constant.” Unless stated otherwise, all measurements are at standard conditions including temperature and pressure.

As used herein, a phrase referring to “at least one of” a list of items refers to any combination of those items, including single members. As an example, “at least one of: A, B, or C” is intended to cover: A; B; C; A and B; A and C; B and C; and A, B, and C. Conjunctive language such as the phrase “at least one of X, Y and Z,” unless specifically stated otherwise, is understood with the context as used in general to convey that an item, term, etc. may be at least one of X, Y or Z. Thus, such conjunctive language is not generally intended to imply that certain embodiments require at least one of X, at least one of Y, and at least one of Z to each be present. The headings provided herein, if any, are for convenience only and do not necessarily affect the scope or meaning of the devices and methods disclosed herein.

Accordingly, the claims are not intended to be limited to the embodiments shown herein but are to be accorded the widest scope consistent with this disclosure, the principles and the novel features disclosed herein.

What is claimed is:

1. A structure comprising:
an active element comprising:
a frontside and a backside opposite the frontside;
a plurality of vias extending from the backside vertically through a portion of the active element; and
an active region nearer to the frontside than the backside;
a power redistribution element disposed on the backside of the active element, the power redistribution element comprising:
a frontside and a backside opposite the frontside,
a first plurality of contact pads disposed on the frontside; and
a second plurality of contact pads disposed on the backside,
wherein a pitch of the first plurality of contact pads is smaller than a pitch of the second plurality of contact pads,
wherein the first plurality of contact pads is electrically coupled to the plurality of vias.

2. The structure of claim 1, further comprising:
a power delivery die comprising a frontside and a backside opposite the frontside, wherein the frontside is in electrical contact with the second plurality of contact pads of the power redistribution element.

3. The structure of claim 1, wherein the power redistribution element is configured to carry power and ground and is not configured to carry logic signals.

4. The structure of claim 1, wherein the power redistribution element comprises an interposer.

5. The structure of claim 4, wherein the power redistribution element further comprises a hybrid bonding layer disposed on the frontside of the power redistribution element, and wherein the power redistribution element further comprises a hybrid bonding layer disposed on the backside of the power redistribution element.

6. The structure of claim 1, wherein the power redistribution element is at least partially deposited on the backside of the active element.

7. The structure of claim 2, wherein the frontside of the power delivery die is hybrid bonded to the backside of the power redistribution element, and wherein the frontside of the power redistribution element is hybrid bonded to the backside of the active element.

8. The structure of claim 2, further comprising a passive element disposed between the power delivery die and the power redistribution element.

9. The structure of claim 1, wherein power is delivered through the power redistribution element to the backside of the active element.

10. A structure comprising:
an active element having a frontside and a backside opposite the frontside, the active element having active circuitry nearer the frontside than the backside; and
a power redistribution element having a frontside hybrid bonded to the backside of the active element, the power redistribution element comprising a first plurality of contact pads on the frontside of the power redistribution element and a second plurality of contact pads on a backside of the power redistribution element opposite the frontside of the power redistribution element,
wherein a pitch of the first plurality of contact pads is smaller than a pitch of the second plurality of contact pads, and
wherein the power redistribution element is configured to supply at least one of power and ground to the active element.

11. The structure of claim 10, wherein the active element comprises vias extending from the backside of the active element to the active circuitry.

12. The structure of claim 10, further comprising:
a power delivery die having a frontside and a backside opposite the frontside,
wherein the frontside of the power delivery die is hybrid bonded to the backside of the power redistribution element.

13. The structure of claim 10, wherein the at least one of power and ground is carried through the power redistribution element and delivered to the backside of the active element.

14. A method comprising:
forming a first interposer comprising:
a first frontside;
a first backside opposite the first frontside;
first frontside contacts disposed at the first frontside, the first frontside contacts arranged in a first frontside arrangement and configured to electrically connect to vias on a backside of a first active element; and
first backside contacts disposed at the first backside, the first backside contacts arranged in a first backside pattern and configured to electrically connect to a first power delivery die.

15. The method of claim 14, wherein the first interposer further comprises a first frontside hybrid bonding surface disposed on the first frontside, and wherein the first interposer further comprises a first backside hybrid bonding surface disposed on the first backside.

16. The method of claim 14, wherein the first interposer is configured to deliver a first power from the first power delivery die to the first backside of the first active element.

17. The method of claim 14, further comprising:
forming a second interposer comprising:
a second frontside;
a second backside opposite the second frontside;
second frontside contacts disposed at the second frontside, the second frontside contacts arranged in a second frontside arrangement and configured to electrically connect to vias on a backside of a second active element; and
second backside contacts disposed at the second backside, the second backside contacts arranged in a second backside pattern and configured to electrically connect to a second power delivery die.

18. The method of claim 17, wherein the first frontside arrangement is different from the second frontside arrangement.

19. The method of claim 18, wherein the first backside pattern is the same as the second backside pattern.

20. The method of claim 17, wherein a pitch of the first backside pattern and the second backside pattern is greater than a pitch of the first frontside arrangement and a pitch of the second frontside arrangement.
